(19) United States
(12) Patent Application Publication
(10) Pub. No.: US 2024/0324401 A1
(43) Pub. Date: Sep. 26, 2024

(54) DISPLAY DEVICE AND METHOD OF MANUFACTURING THE SAME

(71) Applicant: Samsung Display Co., Ltd., Yongin-si (KR)

(72) Inventors: EUN-KYUNG YEON, Yongin-si (KR); JOOHYEON LEE, Yongin-si (KR); Jun Yeub LEE, Yongin-si (KR); HOIKWAN LEE, Yongin-si (KR)

(73) Assignee: Samsung Display Co., Ltd., Yongin-si, Gyeonggi-do (KR)

(21) Appl. No.: 18/536,438

(22) Filed: Dec. 12, 2023

(30) Foreign Application Priority Data
Mar. 21, 2023 (KR) 10-2023-0036658

(51) Int. Cl. H10K 59/80

(52) U.S. Cl. CPC H10K 59/872; H10K 59/8791

(57) ABSTRACT

Provided is a display device which includes a display panel, an anti-reflection layer disposed on the display panel, and a window disposed on the anti-reflection layer. The window includes a first portion including a first resin and disposed on the edge portion of the anti-reflection layer, and a second portion including a second resin and covering at least a portion of the first portion. The curing rate of the first resin is greater than the curing rate of the second resin. Thus, the display device may include the window having a small thickness and a smooth edge portion.

### CROSS-REFERENCE TO RELATED APPLICATION(S)

This application claims priority to and benefits of Korean Patent Application No. 10-2023-0036658 under 35 U.S.C. § 119, filed on Mar. 21, 2023, the entire contents of which are incorporated herein by reference.

### BACKGROUND

### 1. Technical Field

Embodiments relate to a display device and a method of manufacturing the display device. More particularly, the embodiments relate to a display device including a window directly disposed on a display module, and a display device manufacturing method by which a window is formed by directly coating a display module.

### 2. Description of the Related Art

A display device is used for various multimedia devices, such as a television, a mobile phone, a tablet computer, and a game console, to provide image information to users. The display device may include a display module and a window.

The window included in the display device effectively transmits image information provided from the display module to the outside and protects the display module from the outside. The window may be coupled to the display module through an additional adhesive layer or be directly disposed by coating the display module.

### SUMMARY

Embodiments provide a display device including a window capable of improving reliability.

Embodiments also provide a display device manufacturing method capable improving reliability and processability.

However, embodiments of the disclosure are not limited to those set forth herein. The above and other embodiments will become more apparent to one of ordinary skill in the art to which the disclosure pertains by referencing the detailed description of the disclosure given below.

In an embodiment, a display device may include: a display panel; an anti-reflection layer disposed on the display panel; and a window disposed on the anti-reflection layer, wherein the window may include a first portion including a first resin and disposed on an edge portion of the anti-reflection layer, and a second portion including a second resin and covering at least a portion of the first portion, and a curing rate of the first resin is greater than a curing rate of the second resin.

In an embodiment, the first portion of the window may have a closed line shape in plan view, and an upper surface of the first portion of the window may have a curvature.

In an embodiment, a space surrounded by the first portion of the window may be covered by the second portion of the window.

In an embodiment, the window may be directly disposed on the anti-reflection layer.

In an embodiment, the display panel may include a display region and a non-display region surrounding the display region, the window may further include a light blocking layer overlapping the non-display region in plan view, and the first portion of the window may be directly disposed on the light blocking layer.

In an embodiment, the display panel may include a first non-bending region, a bending region, and a second non-bending region which are arranged along a first direction, and in plan view, the anti-reflection layer may overlap the first non-bending region and at least a portion of the bending region.

In an embodiment, the display device may further include an adhesive layer disposed between the display panel and the anti-reflection layer, and a bending protective layer disposed on the display panel, wherein the display panel may include a first non-bending region, a bending region, and a second non-bending region which are arranged along a first direction, and the adhesive layer may overlap the first non-bending region and not overlap the bending region in plan view, and the bending protective layer may be spaced apart from the anti-reflection layer.

In an embodiment, the second portion of the window may include: a flat portion including a substantially flat upper surface; and a curved portion including a curved upper surface and surrounding the flat portion in plan view, wherein the curved portion may have a width of about 3 mm or less.

In an embodiment, the window may have a thickness of about 200 μm to about 700 μm.

In an embodiment, a method of manufacturing a display device may include preparing a display module including a display panel and an anti-reflection layer disposed on the display panel; and forming a window on the display module, wherein the forming of the window may include forming a dam on an edge portion of the anti-reflection layer, and forming a window coating layer on the anti-reflection layer.

In an embodiment, the forming of the dam may include: applying a resin on the edge portion of the anti-reflection layer; and temporarily curing the resin.

In an embodiment, the forming of the window coating layer may include: applying a resin to cover a space, which is surrounded by the dam, and at least a portion of the dam; and curing the dam and the resin.

In an embodiment, the dam may have a closed line shape in plan view, and an upper surface of the dam may have a curvature.

In an embodiment, the window coating layer may be transparent.

In an embodiment, the display panel may include a display region and a non-display region surrounding the display region, and the forming of the window may further include forming a light blocking layer on the anti-reflection layer overlapping the non-display region in plan view.

In an embodiment, in the forming of the dam, the dam may be formed on the light blocking layer.

In an embodiment, the display panel may include a first non-bending region, a bending region, and a second non-bending region which are arranged along a first direction, and the anti-reflection layer may overlap the first non-bending region and at least a portion of the bending region in plan view.

In an embodiment, the display module may further include an adhesive layer disposed between the display panel and the anti-reflection layer and a bending protective layer disposed on the display panel, the display panel may include a first non-bending region, a bending region, and a second non-bending region which are arranged along a first direction, and the adhesive layer may overlap the first non-bending region and may not overlap the bending region in plan view, and the bending protective layer may be spaced apart from the anti-reflection layer.

In an embodiment, the window coating layer may include: a flat portion including a substantially flat upper surface; and a curved portion including a curved upper surface and surrounding the flat portion in plan view, wherein the curved portion may have a width of about 3 mm or less.

In an embodiment, the window may have a thickness of about 200 μm to about 700 μm.

### BRIEF DESCRIPTION OF THE DRAWINGS

The accompanying drawings are included to provide a further understanding of the disclosure, and are incorporated in and constitute a part of the disclosure. The drawings illustrate embodiments and, together with the description, serve to explain principles of the disclosure. In the drawings:

FIG. 1A is a combined schematic perspective view of a display device according to an embodiment;

FIG. 1B is an exploded schematic perspective view of a display device according to an embodiment;

FIG. 2 is a schematic plan view of a display panel according to an embodiment;

FIG. 3 is a schematic cross-sectional view of a display panel according to an embodiment;

FIG. 4 is a schematic plan view of a display device according to an embodiment;

FIG. 5 is a schematic cross-sectional view of a display device according to an embodiment;

FIGS. 6A and 6B are schematic cross-sectional views illustrating a display device according to an embodiment;

FIG. 7 is a flowchart of a method of manufacturing a display device according to an embodiment; and

FIGS. 8A, 8B, 9A, 9B, 10A, 10B, 11A, 11B, 12A, and 12B are schematic views respectively illustrating operations of a method of manufacturing a display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, a display device and a method of manufacturing the display device according to embodiments will be described with reference to the drawings.

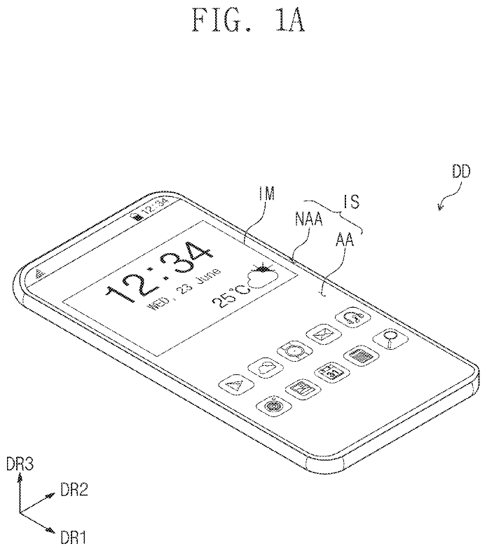

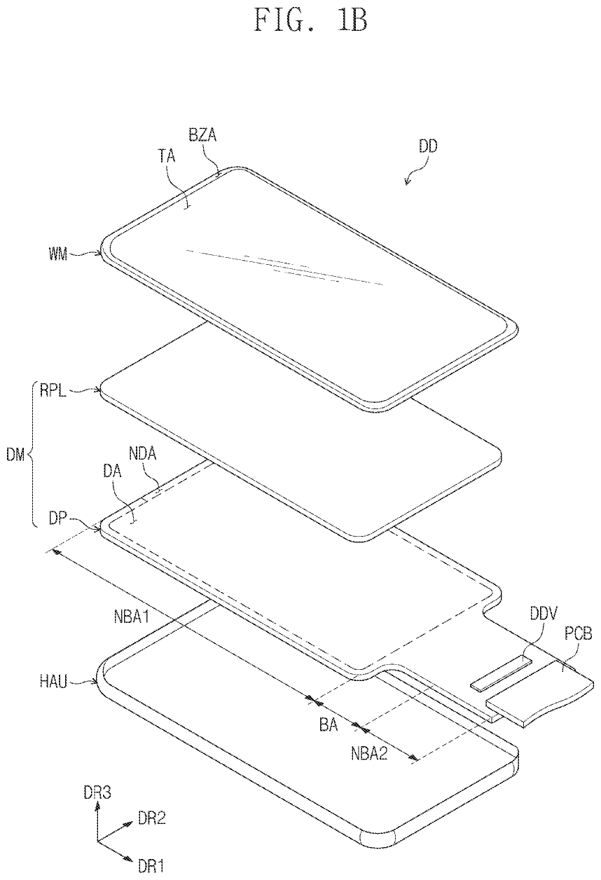

FIG. 1A is a combined schematic perspective view of a display device DD according to an embodiment.

The display device DD may be a device activated in response to an electrical signal. The display device DD may include various embodiments. For example, the display device DD may be a personal computer, a laptop computer, a personal digital assistant, a car navigation unit, a game console, a smartphone, a tablet computer, a camera, and the like. For example, these are examples, and the display device DD may also be implemented as other display devices. In this embodiment, the display device DD is illustrated as a smartphone.

For example, in FIG. 1A and the following drawings, a first direction DR1, a second direction DR2, and a third direction DR3 are illustrated, and the directions indicated by the first direction DR1, the second direction DR2, and the third direction DR3 illustrated herein may be relative and may thus be changed to other directions. In the disclosure, the first direction DR1 and the second direction DR2 may be orthogonal to each other, and the third direction DR3 may be a normal direction of a plane defined by the first direction DR1 and the second direction DR2.

In the disclosure, the wording “on a plane” or “in plan view” may mean a state when viewing on a plane defined by the first direction DR1 and the second direction DR2. For example, the thickness direction of the display device DD may be a direction parallel to the third direction DR3 which is a normal direction of a plane defined by the first direction DR1 and the second direction DR2. A front surface (or upper surface) and a rear surface (or lower surface) of each member forming the display device DD may be defined based on the third direction DR3.

The display device DD may display an image IM, in the third direction DR3, on a display surface IS parallel to a plane defined by the first direction DR1 and the second direction DR2. The display surface IS on which the image IM is displayed may correspond to the front surface of the display device DD. The image IM may include not only a dynamic image but also a static image. In FIG. 1A, a clock display and application icons are illustrated as the images IM.

FIG. 1A illustrates the display device DD including a flat display surface IS. However, a form of the display surface IS of the display device DD is not limited thereto, and may be curved or three-dimensional.

The display surface IS may include an active region AA and a peripheral region NAA adjacent to the active region AA. The peripheral region NAA may be a region in which an image is not displayed. However, embodiments are not limited thereto, and the peripheral region NAA may be omitted.

The display device DD may be flexible. The wording “flexible” means a bendable characteristic, and may include all of a completely foldable structure as well as a structure which is bendable to the level of several nanometers. For example, a flexible display device DD may include a curved display device or a foldable display device. However, the display device DD is not limited thereto, and may be rigid.

For example, the display device DD may detect an external input applied from the outside. The external input may have various forms such as pressure, temperature, light, etc., applied from the outside. The external input may include not only an input from a touch of the display device DD (for example, touch by user's hand or pen) but also an input (for example, hovering input) applied by approaching the display device DD.

FIG. 1B is an exploded schematic perspective view of a display device DD according to an embodiment.

The display device DD may include a window WM and a display module DM. The display module DM may include a display panel DP, an anti-reflection layer RPL, a driver chip DDV, and a printed circuit board PCB.

In the disclosure, the wording “a region/portion corresponds to a region/portion” means “overlapping each other” and is not limited to having the same area and/or the same shape.

The display panel DP may include a first non-bending region NBA1, a bending region BA, and a second non-bending region NBA2 which are arranged along the first direction DR1. The bending region BA may extend from the first non-bending region NBA1 along the first direction DR1, and the second non-bending region NBA2 may extend from the bending region BA along the first direction DR1. FIG. 1B illustrates an unfolded state before the display panel DP is mounted on the display device DD. As the display device DD of FIG. 1A, the first non-bending region NBA1 and the second non-bending region NBA2 of the display panel DP may be respectively disposed on different planes. A bending shape of the bending region BA will be described later.

A display region DA of the display panel DP may be defined in the first non-bending region NBA1. The display region DA may be activated in response to an electrical signal and may be a region in which an image is displayed. The display region DA may correspond to a transmission region TA of a later-described window WM. An image displayed in the display region DA may be visible from the outside through the transmission region TA.

The length of a portion of the bending region BA in the second direction DR2 and the length of the second non-bending region NBA2 in the second direction DR2 may be smaller than the length of the first non-bending region NBA1 in the second direction DR2. However, the shapes of the first non-bending region NBA1, the bending region BA, and the second non-bending region NBA2 are not limited thereto.

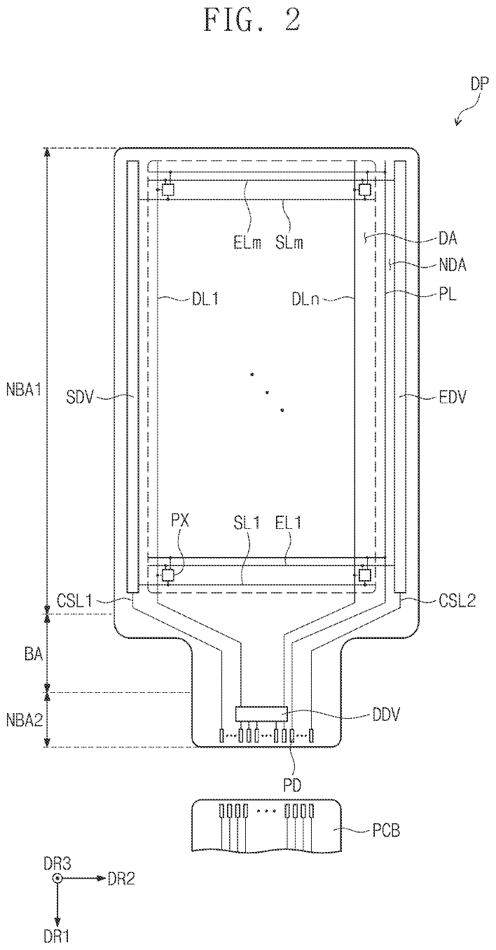

The display panel DP may include the display region DA and a non-display region NDA around the display region DA. The display region DA and the non-display region NDA may be defined based on the presence or absence of pixels PX (see FIG. 2). The display region DA and the non-display region NDA may correspond to (or overlap) the transmission region TA and a bezel region BZA, respectively.

The non-display region NDA may be adjacent to the display region DA. For example, the non-display region NDA may surround the display region DA. However, embodiments are not limited thereto, and the non-display region NDA may be defined in various shapes. The second non-bending region NBA2 and the bending region BA may be some regions of the non-display region NDA. The non-display region NDA may correspond to a region other than the display region DA defined in the first non-bending region NBA1, the bending region BA, and the second non-bending region NBA2.

The non-display region NDA may be a region in which a driving circuit or driving wiring for driving display region DA, various signal lines providing electrical signals, and pads are disposed. The bezel region BZA may prevent components, of the display panel DP, which are disposed in the non-display region NDA from being viewed (or recognized) to the outside.

A driver chip DDV may be disposed in the second non-bending region NBA2 of the display panel DP. The driver chip DDV may be manufactured in a form of an integrated circuit chip, and mounted on the second non-bending region NBA2.

The printed circuit board PCB may be disposed adjacent to an end portion of the second non-bending region NBA2. The printed circuit board PCB may be spaced apart from the driver chip DDV in the first direction DR1.

The printed circuit board PCB may include electronic elements which are mounted within a substrate. The electronic elements may be electrically connected via a circuit wiring. The printed circuit board PCB may be connected to pads disposed in the second non-bending region NBA2 and may be electrically connected to the display panel DP. For example, the printed circuit board PCB may be electrically connected, via a connector, to a motherboard of an electronic module forming the display device DD.

The anti-reflection layer RPL may be disposed on the display panel DP. The anti-reflection layer RPL may be formed through a continuous process and disposed (e.g., directly disposed) on the display panel DP. In another example, the anti-reflection layer RPL may be bonded to the display panel DP by an adhesive layer.

The anti-reflection layer RPL may reduce an external light reflectance. In case that external light emitted toward the display panel DP is reflected from the display panel DP and is provided again to an external user, the external light may be viewed by the user in case that the external light is reflected from a mirror.

In order to prevent this phenomenon, the anti-reflection layer RPL may include light-blocking pattern layers. For example, the anti-reflection layer RPL may include color filters which display the same colors as pixels of the display panel DP. The color filters may be disposed between the light-blocking pattern layers and may include a first color-color filter, a second color-color filter, and a third color-color filter which respectively correspond to a first color pixel, a second color pixel, and a third color pixel.

The anti-reflection layer RPL may include a polarizing film for reducing an external light reflectance. The polarizing film may include a retarder and/or a polarizer.

The window WM may be disposed on the display panel DP. The window WM may protect the display panel DP against an external impact.

The window WM may include a transmission region TA and a bezel region BZA. The transmission region TA and the bezel region BZA of the window WM may respectively correspond to the display region DA and the non-display region NDA of the display panel DP.

The transmission region TA may be an optically transparent region. FIG. 1B illustrates the transmission region TA as a quadrilateral shape with rounded vertices. However, this is merely illustrated as an example. The transmission region TA may have various shapes, and a shape thereof is not limited to any one embodiment.

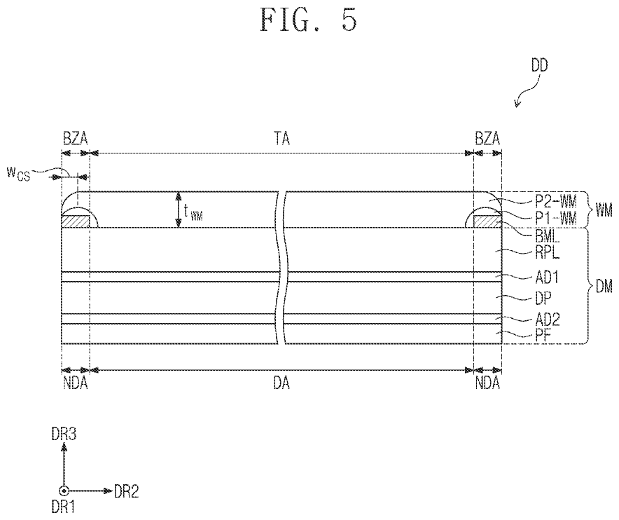

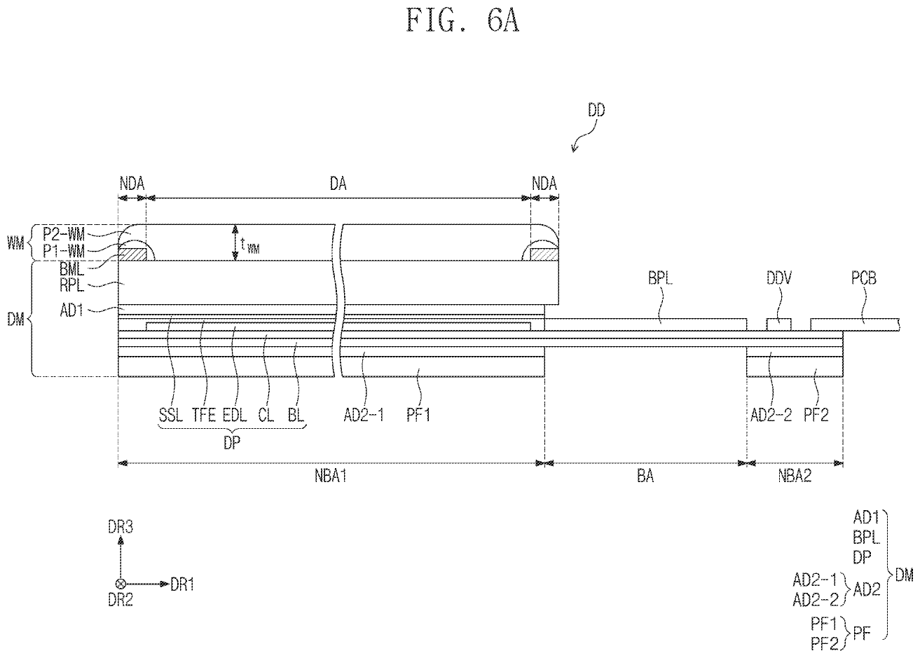

The bezel region BZA may be a region having a relatively lower light transmittance than the transmission region TA. The bezel region BZA may be a region in which a light blocking layer BML (see FIG. 5) is disposed, and have a certain color. The bezel region BZA may be adjacent to the transmission region TA and surround the transmission region TA. The bezel region BZA may define a shape of the transmission region TA. However, embodiments are not limited to what is illustrated. The bezel region BZA may be disposed adjacent only to a side (e.g., single side) of the transmission region TA, and some portions thereof may be omitted.

The detailed content of the window WM will be described later.

The display device DD may further include a housing HAU. The housing HAU may be coupled to the window WM to form the exterior of the display device DD, and provide an inner space in which components of the display device DD may be accommodated.

The housing HAU may be disposed below the display panel DP and accommodate the display panel DP. The housing HAU may absorb an impact applied from the outside and may prevent a foreign substance/moisture, etc., from being infiltrated into the display panel DP, thereby protecting the display panel DP. In an embodiment, the housing HAU may be provided to have a form in which accommodation members are coupled.

The display device DD may further include an electronic module including various functional modules for operating the display panel DP, a power supply module which supplies the power required for the display device DD, and a bracket which is coupled to the display panel DP and/or the housing HAU to partition (or divide) the inner space of the display device DD.

FIG. 2 is a schematic plan view of a display panel DP according to an embodiment.

Referring to FIG. 2, the display panel DP may include pixels PX disposed in a display region DA and signal lines electrically connected to the pixels PX. The display panel DP may include pads PD, a scan driver SDV, and an emission driver EDV which are disposed in a non-display region NDA.

The pixels PX may each include a pixel driving circuit which is connected to a later-described light-emitting element, transistors (for example, switching transistor, driving transistor, etc.) connected to the light-emitting element, and a capacitor. The pixels PX may each emit light in response to an applied electrical signal.

Signal lines may include scan lines SL1 to SLm, data lines DL1 to DLn, light-emitting lines EL1 to ELm, first and second control lines CSL1 and CSL2, and a power supply line PL. Herein, m and n are a natural number. The pixels PX may be respectively connected to corresponding scan lines among the scan lines SL1 to SLm and corresponding data lines among the data lines DL1 to DLn. For example, more various types of signal lines may be provided in the display panel DP according to a configuration of the pixel driving circuit of the pixels PX.

The scan driver SDV and the emission driver EDV may be disposed in the non-display region NDA. The scan driver SDV and the emission driver EDV may be respectively disposed adjacent to long-sides of the non-display region NDA of the first non-bending region NBA1.

The scan lines SL1 to SLm may extend in the second direction DR2 to be connected to the scan driver SDV. The data lines DL1 to DLn may extend in the first direction DR1 to be connected to the driver chip DDV via the bending region BA. The light-emitting lines EL1 to ELm may extend in the second direction DR2 to be connected to the emission driver EDV.

The power supply line PL may extend in the first direction DR1 and be disposed between the display region DA and the emission driver EDV. However, embodiments are not limited thereto, and the power supply line PL may be disposed between the display region DA and the scan driver SDV. The power supply line PL may extend up to the second non-bending region NBA2 via the bending region BA. The power supply line PL may be connected to corresponding pad PD among the pads PD disposed on a lower end portion of the second non-bending region NBA2, and receive a voltage. The power supply line PL may provide a reference voltage to the pixels PX via connection lines.

The data lines DL1 to DLn may be connected to the corresponding pads PD via the driver chip DDV. For example, the data lines DL1 to DLn may be connected to the driver chip DDV, and the driver chip DDV may be connected to each of the pads PD corresponding to the data lines DL1 to DLn.

The pads PD may be arranged on the non-display region NDA of the second non-bending region NBA2 along a direction. The pads PD may be disposed adjacent to an end portion of the second non-bending region NBA2 extending in the first direction DR1, and be arranged along the second direction DR2. The pads PD may be portions which are connected to a printed circuit board PCB. The pads PD may be respectively connected to corresponding signal lines among signal lines.

The printed circuit board PCB may be connected to the pads PD and control operations of the scan driver SDV, the emission driver EDV, and the driver chip DDV. The printed circuit board PCB may be a board on which a timing controller implemented in a form of an integrated circuit chip is mounted. The timing controller may generate a scan control signal, a data control signal, and a light-emitting control signal in response to control signals received from the outside.

The scan driver SDV may generate scan signals in response to a scan control signal. The scan signals may be applied to the pixels PX via the scan lines SL1 to SLm. The data driver of the driver chip DDV may generate data voltages corresponding to image signals in response to a data control signal. The data voltages may be applied to the pixels PX via the data lines DL1 to DLn. The emission driver EDV may generate light-emitting signals in response to a light-emitting control signal. The light-emitting signals may be applied to the pixels PX via the light-emitting lines EL1 to ELm.

The pixels PX may receive the data voltage in response to the scan signals. The pixels PX may emit light having a luminance corresponding to each of the data voltages in response to the light-emitting signals and thus display images. By the pixels PX, an image may be displayed through the display region DA defined in the first non-bending region NBA1.

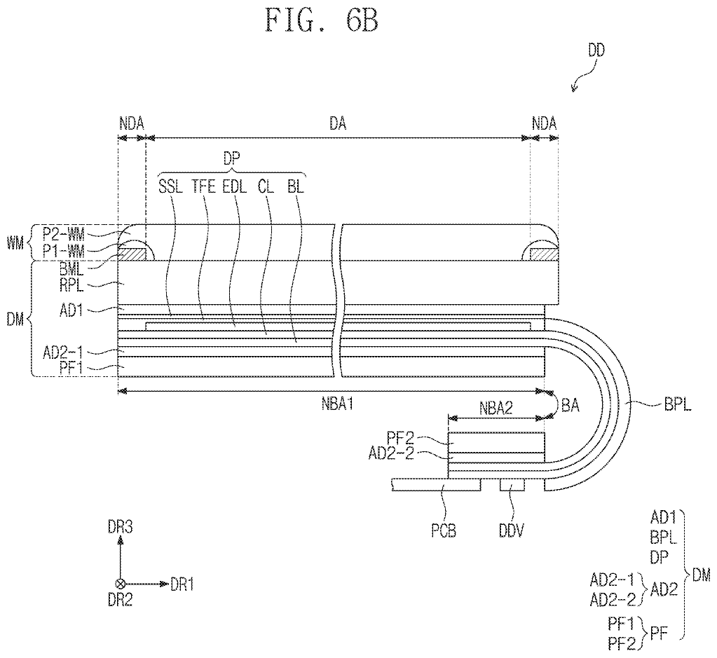

The signal lines extending from the first non-bending region NBA1 to the second non-bending region NBA2 may be arranged on the bending region BA of the display panel DP. Since a bending protective layer BPL (see FIG. 6A) covers the bending region BA, the signal lines disposed on the bending region BA may be protected against an external impact.

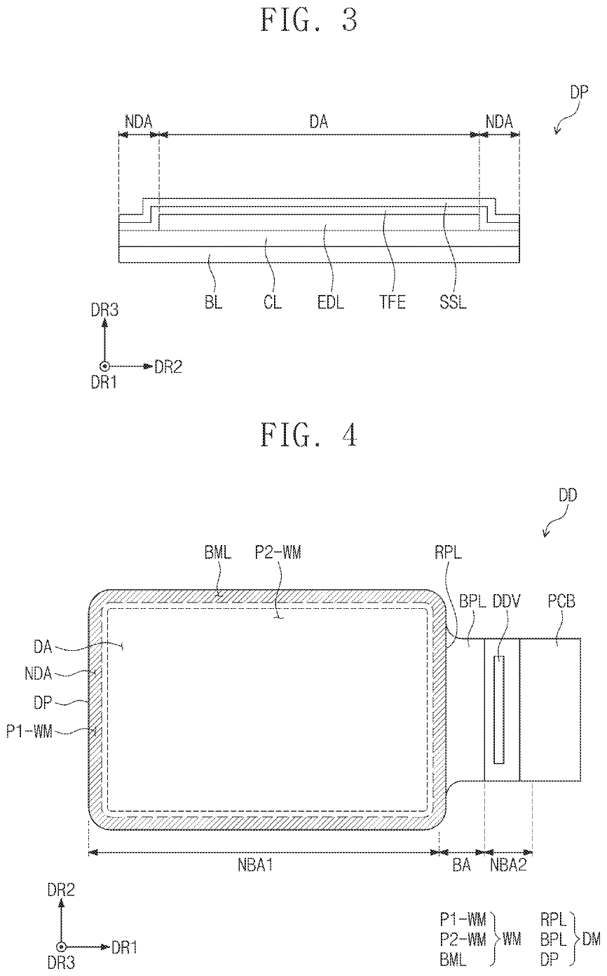

FIG. 3 is a schematic cross-sectional view of a display panel DP according to an embodiment. FIG. 3 may be a schematic cross-sectional view illustrating a position at which a display region DA is disposed in the first non-bending region NBA1 (see FIG. 1B) of the display panel DP.

Referring to FIG. 3, the display panel DP may include a base layer BL, a circuit layer CL, a light-emitting element layer EDL, and an encapsulation layer TFE. The display panel DP may include the display region DA and a non-display region NDA. The display region DA of the display panel DP may correspond to the transmission region TA (see FIG. 1B), and the non-display region NDA may correspond to the bezel region BZA (see FIG. 1B).

The base layer BL may provide a base surface on which the circuit layer CL, the light-emitting element layer EDL, and the encapsulation layer TFE are disposed. The base layer BL may be a rigid substrate, or a flexible substrate capable of being bent, folded, rolled, or the like. The base layer BL may be a glass substrate, a metal substrate, a polymer substrate, or like. However, embodiments are not limited thereto, and the base layer BL may include an inorganic layer, an organic layer, or an organic/inorganic composite material layer.

The base layer BL may have a multi-layered structure. For example, the base layer BL may include a first synthetic resin layer, a multi- or single-layered inorganic layer, and a second synthetic resin layer which is disposed on the multi-layered inorganic layer or a single-layered inorganic layer. For example, the first and second synthetic resin layers may each include a polyimide based-resin, but embodiments are not limited thereto.

The circuit layer CL may be disposed on the base layer BL. The circuit layer CL may include insulating layers, conductive layers, and a semiconductor layer. The conductive layers of the circuit layer CL may form the signal lines or the driving circuit of the pixels. The insulating layers may include at least one inorganic film and at least one organic film.

The light-emitting element layer EDL may be disposed on the circuit layer CL. The light-emitting element layer EDL may include at least one light-emitting element. For example, the light-emitting element included in the light-emitting element layer EDL may include an organic light-emitting element, an inorganic light-emitting element, an organic-inorganic light-emitting element, a micro LED, a nano LED, a quantum dot light-emitting element, an electrophoretic element, an electrowetting element, and the like.

The encapsulation layer TFE may be disposed on the light-emitting element layer EDL. The encapsulation layer TFE may seal the light-emitting element layer EDL. The encapsulation layer TFE may be a thin-film encapsulation layer. The encapsulation layer TFE may protect the light-emitting element layer EDL against moisture, oxygen, and foreign substances such as dust particles. The encapsulation layer TFE may include thin films. The thin-film encapsulation layer may have a stacked structure of an inorganic film/an organic film/an inorganic film. However, the encapsulation layer TFE is not limited thereto, and an encapsulation substrate may be provided instead of the thin-film encapsulation layer. The encapsulation substrate may face the base layer BL, and the circuit layer CL and the light-emitting element layer EDL may be disposed between the encapsulation substrate and the base layer BL. For example, the display device DD may include a sealant which bonds the base layer BL and the encapsulation substrate.

The sensor layer SSL may be disposed on the encapsulation layer TFE. The sensor layer SSL may detect an input applied from the outside. The input applied from the outside may be provided in various forms. For example, the external input may include an external input in various forms, such as a part of a user's body, a stylus pen, light, heat, pressure, or the like. For example, the external input may have a form of not only an input from a touch by a part of a user's body such as a user's hand but also an input (for example, hovering input) from a spatial touch that approaches or is adjacent to the sensor layer. The sensor layer SSL may be disposed (e.g., directly disposed) on the encapsulation layer TFE. In an embodiment, the sensor layer SSL may be manufactured on the encapsulation layer TFE by a continuous process. However, embodiments are not limited thereto. The sensor layer SSL may be provided as an individual panel and bonded to the encapsulation layer TFE via the adhesive layer. In another example, the sensor layer SSL may be omitted.

FIG. 4 is a schematic plan view of a display device DD according to an embodiment. FIG. 5 is a schematic cross-sectional view of a display device DD according to an embodiment. FIGS. 6A and 6B are schematic cross-sectional views illustrating a display device DD according to an embodiment. The same/similar reference numerals or symbols are used for the same/similar components which have been described with reference to FIGS. 1A to 3, and a redundant description thereof will be omitted for descriptive convenience.

FIG. 4 may be a schematic plan view of the display device DD when viewed in the third direction DR3, FIG. 5 may be a schematic cross-sectional view of the display device DD taken along the second direction DR2, and FIGS. 6A and 6B may be schematic cross-sectional views of the display device DD taken along the first direction DR1.

The anti-reflection layer RPL may overlap the first non-bending region NBA1 and at least a portion of the bending region BA. For example, the anti-reflection layer RPL may extend from the first non-bending region NBA1 to a portion of the bending region BA.

The window WM may be disposed (e.g., directly disposed) on the anti-reflection layer RPL. For example, the window WM may be formed by coating the anti-reflection layer RPL without an additional adhesive member. The forming method will be described later in more detail in a later-described manufacturing method. The thickness t_{WM} of the window WM may be about 200 μm to about 700 μm.

Referring to FIGS. 4 and 5, the window WM may include a first portion P1-WM and a second portion P2-WM. The window WM may further include a light blocking layer BML disposed in a region corresponding to the bezel region BZA.

The first portion P1-WM may be disposed on an edge portion of the anti-reflection layer RPL. The first portion P1-WM may cover the light blocking layer BML, overlap the bezel region BZA in plan view, and overlap a portion of the transmission region TA, which is adjacent to the bezel region BZA. The first portion P1-WM may have a closed line shape in plan view. A portion of the first portion P1-WM may overlap the first non-bending region NBA1, and the other portion of the first portion P1-WM may overlap the bending region BA.

As illustrated in FIG. 5, an upper surface of the first portion P1-WM may have a curvature. For example, the upper surface of the first portion P1-WM may have a semicircular shape. Since the second portion P2-WM is disposed on the first portion P1-WM, the end portion (or edge portion) of the second portion P2-WM may not be sharp and include a smooth curved surface.

The second portion P2-WM may cover at least a portion of the first portion P1-WM. The second portion P2-WM may cover the entirety or a portion of an upper surface of the first portion P1-WM. FIG. 5 illustrates that the first portion P1-WM covers the entire upper surface of the second portion P2-WM. For example, in case that the second portion P2-WM covers a portion of the upper surface of the first portion P1-WM, the second portion P2-WM may cover a portion of the first portion P1-WM, which is adjacent to the display region DA.

For example, in plan view, a space surrounded by the first portion P1-WM may be covered by the second portion P2-WM. The second portion P2-WM may overlap the first non-bending region NBA1.

The upper surface of the second portion P2-WM may be an upper surface of the window WM. As illustrated in FIGS. 5, 6A, and 6B, the upper surface of the window WM may be substantially flat, and an edge portion of the upper surface may include a smooth curved surface. The upper surface of the window WM may include a flat portion which is substantially flat, and a curved portion which has a smooth curved surface and surrounds the flat portion in plan view. As described above, since the window WM includes the first portion P1-WM, an edge portion of the second portion P2-WM may not be sharp, and thus the width w_{cs} of the curved portion may be small. For example, the curved portion may have a width w_{cs} of about 3 mm or less.

The light blocking layer BML may be disposed on the display module DM to define the non-display region NDA. For example, the first portion P1-WM of the window WM may be disposed (e.g., directly disposed) on the light blocking layer BML.

The first portion P1-WM and the second portion P2-WM may each include a resin. The first portion P1-WM may include a first resin, and the second portion P2-WM may include a second resin. The curing rate of the first resin may be greater than the curing rate of the second resin. Since the first portion P1-WM is temporarily cured, and then the second portion P2-WM is coated and mainly cured, the first resin may have a greater curing rate than the second resin.

The first resin and the second resin may be cured from the same material, but embodiments are not limited to the same material. For example, the first resin and the second resin may each include at least one selected from the group consisting of polycarbonate, polymethylmethacrylate, polyimide, polyethylene terephthalate, polyacrylate, polyethylenenaphthalate, polyvinylidene chloride, polyvinylidene difluoride, polystyrene, an ethylene vinylalcohol copolymer, and triacetyl cellulose. However, the first resin and the second resin are not limited thereto.

The first resin and the second resin may be cured from a resin having a viscosity within a wide range. Since the window WM has a structure in which the first portion P1-WM and the second portion P2-WM are included, the edge portion of the upper surface of the window WM may become smooth without performing an additional process even in case that resins having various viscosities are used as the first resin and the second resin. For example, the curved portion of the upper surface of the window WM may have a narrow width. For example, a resin having a viscosity of about 820 cp to about 160,000 cp may be used as the first resin and the second resin.

For example, the first resin and the second resin may each be a transparent material. For example, the first resin and the second resin may each have a light transmittance of about 90% or more. Therefore, the first portion P1-WM and the second portion P2-WM of the window WM may correspond to a transparent transmission region TA except for the bezel region BZA covered by the light blocking layer BML.

For example, FIGS. 4, 5, and 6A illustrate that the first portion P1-WM is a single component. However, the first portion P1-WM is not limited thereto, and may include a plurality of sub portions. For example, in case that the first portion P1-WM includes a plurality of sub portions, the first portion P1-WM may be defined as the plurality of sub portions having different curing rates. In case that the first portion P1-WM includes a plurality of sub portions, a sub portion disposed adjacent to the light blocking layer BML may have a relatively greater curing rate than a sub portion disposed far away from the light blocking layer BML.

The display module DM may further include adhesive layers AD1 and AD2. FIGS. 6A and 6B illustrate two adhesive layers AD1 and AD2, but the adhesive layers may be omitted or added. The first adhesive layer AD1 may be disposed between the display panel DP and the anti-reflection layer RPL, and the second adhesive layer AD2 may be disposed between the display panel DP and a panel protective layer PF. The second adhesive layer AD2 may include a (2-1)-th adhesive layer AD2-1 disposed in the first non-bending region NBA1 of the display panel DP and a (2-2)-th adhesive layer AD2-2 disposed in the second non-bending region NBA2.

For example, the first adhesive layer AD1 may overlap the first non-bending region NBA1 and may not overlap the bending region BA. Accordingly, a portion of the anti-reflection layer RPL disposed in the bending region BA, may be spaced apart from the display panel DP, and thus the anti-reflection layer RPL and the window WM disposed on the anti-reflection layer RPL may not receive a bending stress during a bending operation and may thus be maintained as parallel planes without being bent.

The adhesive layers AD1 and AD2 may each be an optically clear adhesive film (OCA) or an optically clear adhesive resin layer (OCR).

The display module DM may further include the panel protective layer PF disposed below the display panel DP. Referring to FIG. 6A, the panel protective layer PF may be disposed to correspond to the first non-bending region NBA1 and the second non-bending region NBA2 and may not be disposed in the bending region BA. For example, the panel protective layer PF may include a first panel protective layer PF1 corresponding to the first non-bending region NBA1 and a second panel protective layer PF2 corresponding to the second non-bending region NBA2.

Since the panel protective layer PF is disposed only in the first and second non-bending regions NBA1 and NBA2 and is not disposed in the bending region BA, the thickness of the bending region BA of the display panel DP is reduced, and thus bending stress may be reduced. Therefore, the display panel DP may be readily bent.

Referring to FIG. 6A, the panel protective layer PF may include an upper surface adjacent to the display panel DP and a lower surface facing the upper surface. The first and second panel protective layers PF1 and PF2 may each include an upper surface and a lower surface, and the upper surface may mean a surface adjacent to the display panel DP.

The first panel protective layer PF1 may be disposed under the first non-bending region NBA1 of the display panel DP. The first panel protective layer PF1 may be bonded to the display panel DP by the (2-1)-th adhesive layer AD2-1.

Referring to FIG. 6B, in a state where the display panel DP is bent, the second panel protective layer PF2 may be disposed below the first panel protective layer PF1. For example, the lower surface of the second panel protective layer PF2 may face the lower surface of the first panel protective layer PF1. The second panel protective layer PF2 may be bonded to the display panel DP by the (2-2)-th adhesive layer AD2-2.

The panel protective layer PF may include a flexible plastic material. For example, the panel protective layer PF may include at least one of polyethylene terephthalate or polyimide. However, a material of the panel protective layer PF is not limited thereto.

The display module DM may further include a bending protective layer BPL disposed on the display panel DP. The bending protective layer BPL may be disposed on the bending region BA and thus protect the display panel DP from the outside in a bent state. As illustrated in FIGS. 6A and 6B, the bending protective layer BPL may be spaced apart from the anti-reflection layer RPL in the third direction DR3. In another example, the bending protective layer BPL may be spaced apart from the driver chip DDV in the first direction DR1. However, embodiments are not limited thereto, and the bending protective layer BPL may cover the driver chip DDV or may cover a portion of the printed circuit board PCB.

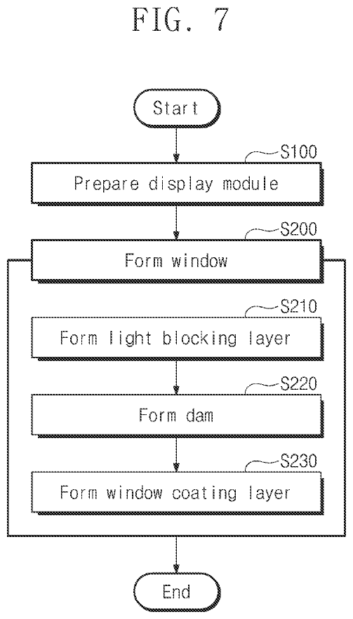

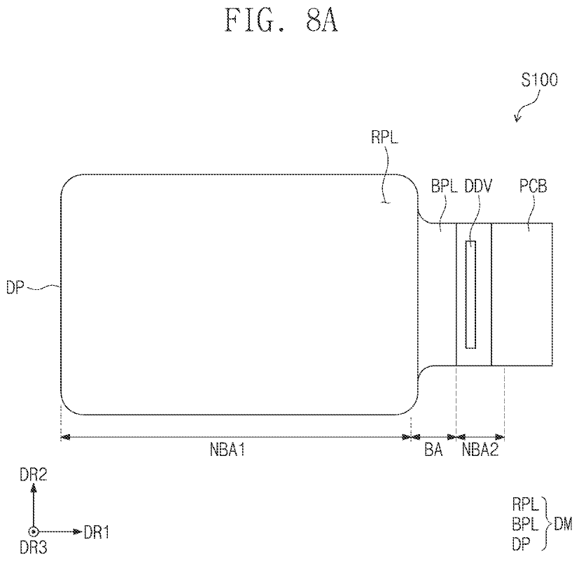

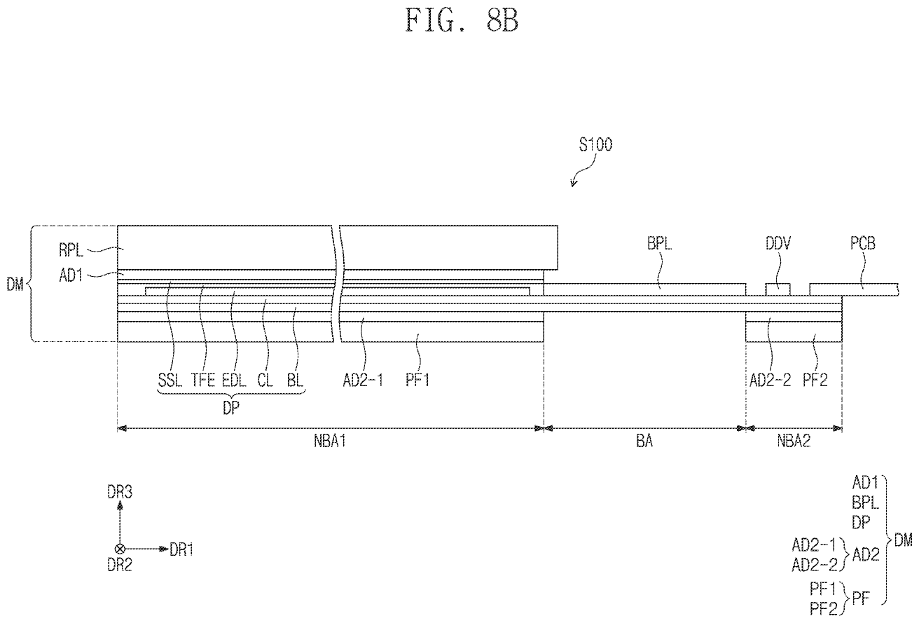

FIG. 7 is a flowchart of a method of manufacturing a display device according to an embodiment. FIGS. 8A, 8B, 9A, 9B, 10A, 10B, 11A, 11B, 12A, and 12B are schematic views respectively illustrating some operations of the method of manufacturing the display device according to an embodiment. The same/similar reference numerals or symbols are used for the components same as/similar to those which have been described in FIGS. 1A, 1B, 2, 3, 4, 5, 6A, and 6B, and the redundant description thereof will be omitted for descriptive convenience.

Referring to FIG. 7, the method of manufacturing the display device may include preparing a display module (S100) and forming a window on the display module (S200). The operation of forming the window (S200) may include forming a light blocking layer (S210), forming a dam (S220), and forming a window coating layer (S230).

FIGS. 8A and 8B are respectively a schematic plan view and a schematic cross-sectional view illustrating an operation of preparing a display module DM (S100). The display module DM may include a display panel DP and an anti-reflection layer RPL disposed on the display panel DP.

The display panel DP may include a first non-bending region NBA1, a bending region BA, and a second non-bending region NBA2 which are arranged along the first direction DR1. In plan view, the anti-reflection layer RPL may overlap the first non-bending region NBA1 and at least a portion of the bending region BA.

The display module DM may further include a first adhesive layer AD1 disposed between the display panel DP and the anti-reflection layer RPL. In plan view, the first adhesive layer AD1 may overlap the first non-bending region NBA1 and may not overlap the bending region BA.

The display module DM may further include a bending protective layer BPL disposed on the display panel DP. The bending protective layer BPL may be disposed in the bending region BA. The bending protective layer BPL may be spaced apart from the anti-reflection layer RPL in the third direction DR3. Therefore, in case that the bending region BA is bent, bending stress may not be applied to the anti-reflection layer RPL.

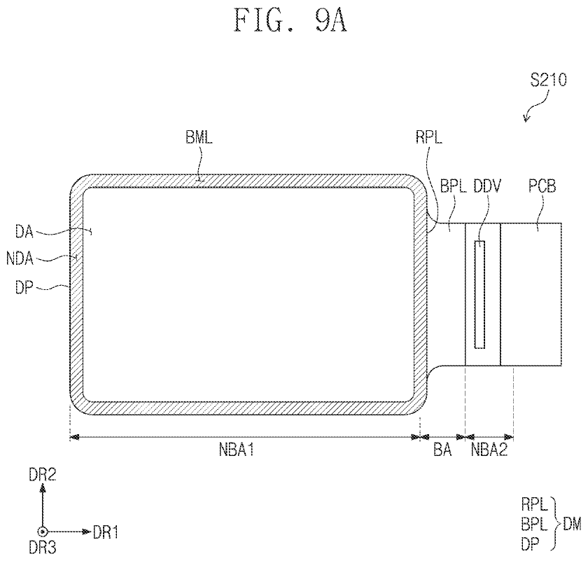

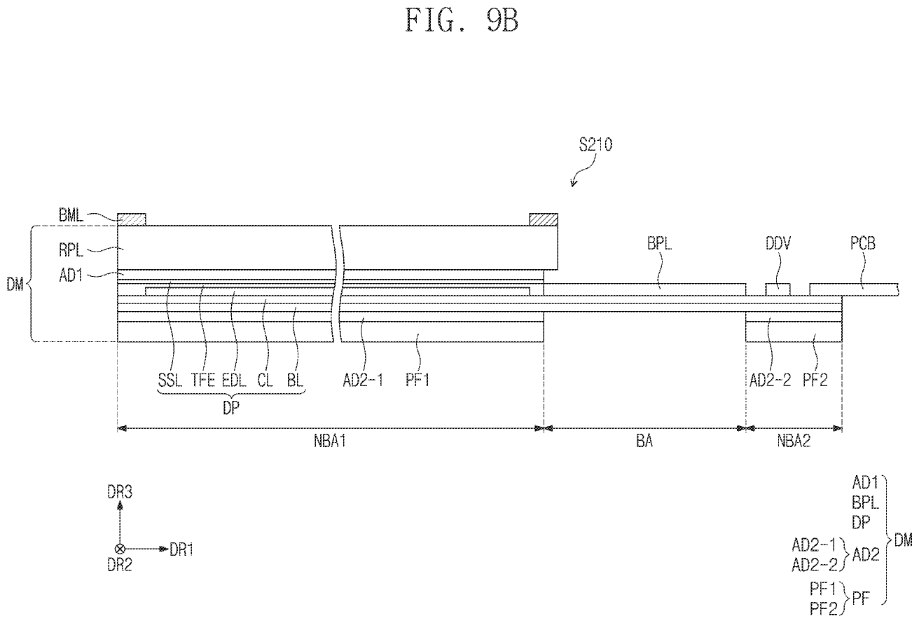

FIGS. 9A and 9B are respectively a schematic plan view and a schematic cross-sectional view illustrating an operation of forming a light blocking layer BML (S210). The light blocking layer BML may be formed on the anti-reflection layer RPL and may be formed in a region overlapping the non-display region NDA of the display panel DP. FIG. 9A illustrates that the light blocking layer BML has a uniform width, but embodiments are not limited thereto. The light blocking layer BML may be formed differently according to a region in which light should be blocked.

The light blocking layer BML may include light blocking ink which blocks light. For example, the light blocking layer BML may include light blocking ink and a base material. The light blocking ink may include carbon black particles, but embodiments are not limited thereto. The light blocking ink may include one or more pigments, dyes, or a mixture thereof in addition to carbon black. The light blocking layer BML may be printed (e.g., directly printed) on the anti-reflection layer RPL through an inkjet method, a silk screen method, or the like. However, a printing method is not limited thereto.

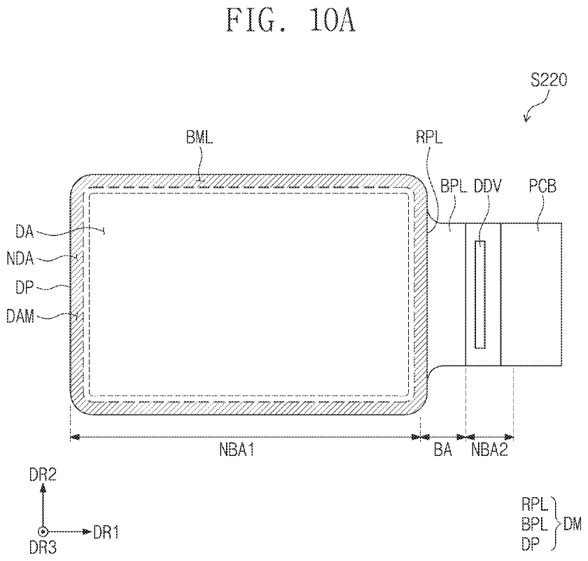

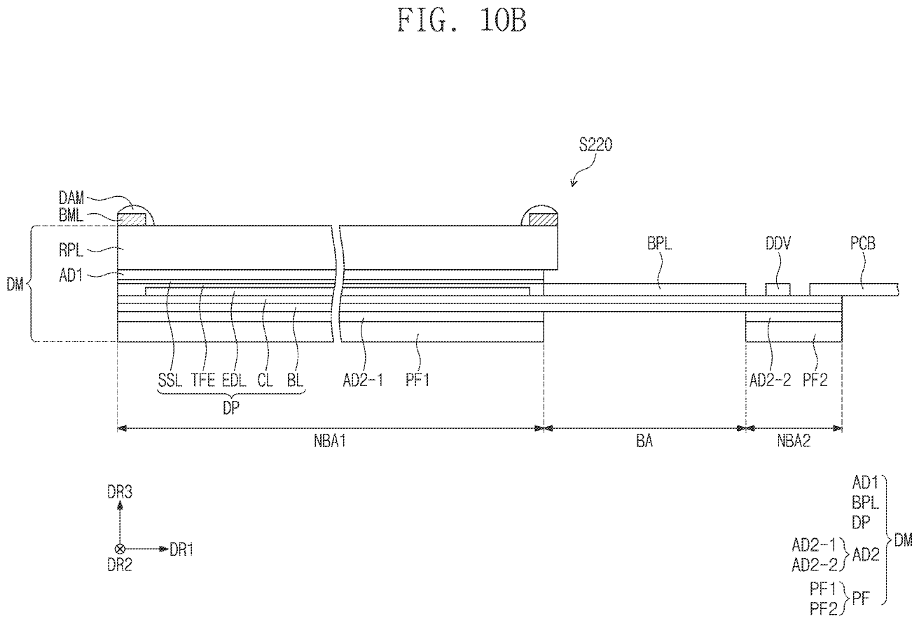

FIGS. 10A and 10B are respectively a schematic plan view and a schematic cross-sectional view illustrating an operation of forming a dam DAM (S220). The operation of forming the dam DAM (S220) may include applying a resin on an edge portion of the anti-reflection layer RPL and temporarily curing the resin. The dam DAM may mean a portion which is applied on the edge portion of the anti-reflection layer RPL and is temporarily cured.

The dam DAM in each of FIGS. 10A and 10B may be a portion corresponding to the first portion P1-WM in each of FIGS. 4 and 5. For example, the dam DAM in each of FIGS. 10A and 10B may be mainly cured, as described below, and correspond to the first portion P1-WM of each of FIGS. 4 and 5.

Referring to FIG. 10A, a resin may be applied on the edge portion of the anti-reflection layer RPL and may be temporarily cured, so that the dam DAM may be formed to have a closed line shape in plan view.

Referring to FIG. 10B, a resin may be applied on a light blocking layer BML. For example, a resin may be applied to cover an upper surface of the light blocking layer BML. Due to surface tension, the resin may be applied such that an upper surface of the resin may have a curvature. The resin may be applied to have an upper surface with a curvature and may be temporarily cured, so that an upper surface of the dam DAM may have a curvature. For example, the upper surface of the dam DAM may have a semicircular shape.

For example, FIGS. 10A and 10B illustrate that the operation of forming the dam DAM (S220) includes applying a resin once and temporarily curing the resin once, but embodiments are not limited thereto. For example, the operation of forming the dam DAM (S220) may include applying a resin at least two times and temporarily curing the resin at least two times. In case that the operation of forming the dam DAM (S220) includes applying a resin at least two times and temporarily curing the resin at least two times, the curing rate of a portion applied adjacent to the light blocking layer BML may be greater than the curing rate of a portion applied far away from the light blocking layer BML. For example, in case that the operation of forming the dam DAM (S220) includes applying a resin at least two times and temporarily curing the resin at least two times, the method may include, in order, primarily applying a resin, temporarily curing the primarily applied resin, secondarily applying a resin on the resin which has been primarily applied and temporarily cured, and temporarily curing the secondarily applied resin. For example, in a finally obtained window, the curing rate of a portion primarily applied adjacent to the light blocking layer BML may be greater than the curing rate of a portion secondarily applied far away from the light blocking layer BML. In the operation of secondarily applying a resin on the resin which has been primarily applied and temporarily cured, the resin may be applied to cover at least a portion of the resin which has been primarily applied and temporarily cured. For example, in case that the operation of forming the dam DAM (S220) includes applying a resin at least two times and temporarily curing the resin at least two times, the upper surface of the dam DAM may be formed to have a curvature, for example, a semicircular shape.

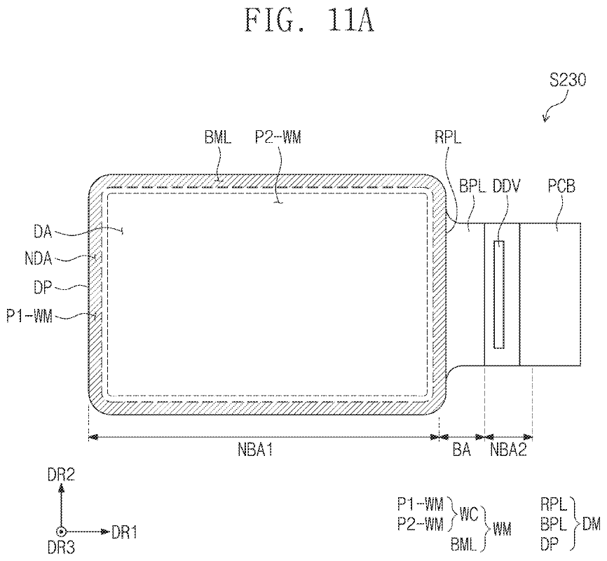

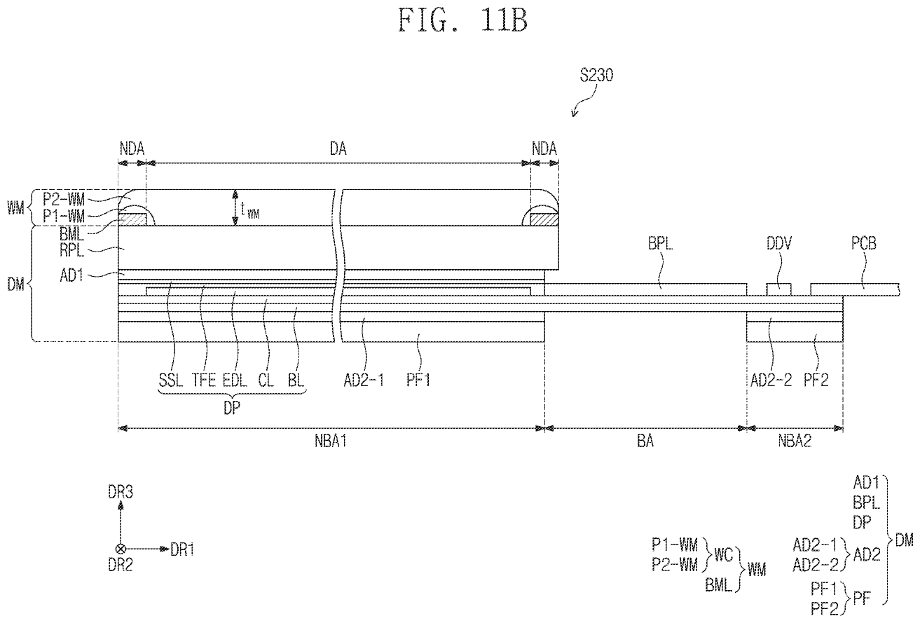

FIGS. 11A and 11B are respectively a schematic plan view and a schematic cross-sectional view illustrating an operation of forming a window coating layer WC (S230). The operation of forming the window coating layer WC (S230) may include applying a resin so as to cover a space surrounded by the dam DAM (see FIG. 10A) and at least a portion of the dam DAM (see FIG. 10B), and curing the dam DAM (see FIG. 10A) and the resin. Herein, the curing may mean a main curing.

The window coating layer WC may include a first portion P1-WM and a second portion P2-WM of the above-described window WM. The first portion P1-WM may correspond to a portion where the dam DAM (see FIG. 10A) is mainly cured, and the second portion P2-WM may correspond to a portion where the resin applied in the operation of forming the window coating layer WC (S230) is mainly cured.

For example, a first resin included in the above-described first portion P1-WM may correspond to the resin which is applied and temporarily cured in the operation of forming the dam DAM (see FIG. 10A) (S220, see FIG. 10A) and then is mainly cured in the operation of forming the window coating layer WC (S230). A second resin included in the above-described second portion P2-WM may correspond to the resin which is applied and mainly cured in the operation of forming the window coating layer WC (S230). Therefore, as described above, the curing rate of the first resin included in the first portion P1-WM may be greater than the curing rate of the second resin included in the second portion P2-WM.

A resin having a viscosity within a wide range may be used as the resin. The window coating layer WC may be formed by first forming the temporarily cured dam DAM (see FIG. 10B) and then applying and mainly curing a resin such that at least a portion of the dam DAM (see FIG. 10B) may be covered. Therefore, even in a case of applying a resin having a various viscosity range, an edge portion of an upper surface of the window coating layer WC may be formed smoothly without an additional process. For example, a resin having a viscosity of about 820 cp to about 160,000 cp may be used as the resin.

For example, a resin may be a transparent material. For example, the mainly cured resin may have a light transmittance of about 90% or more. Therefore, the window coating layer WC may be transparent, and the first portion P1-WM and the second portion P2-WM each may correspond to a transparent transmission region TA except for the bezel region BZA covered by the light blocking layer BML.

Referring to FIG. 11A, the resin may be applied to cover a space surrounded by the dam DAM (see FIG. 10A) in plan view. Therefore, the second portion P2-WM may be formed to cover a space surrounded by the first portion P1-WM formed by mainly curing the dam DAM (see FIG. 10A).

Referring to FIG. 11B, the resin may be applied to cover at least a portion of the dam DAM (see FIG. 10B). Therefore, the second portion P2-WM may be formed to cover at least a portion of the first portion P1-WM.

Herein, the resin may be applied by a dispensing method, a slot die coating method, an inkjet method, and the like, but an application method is not limited thereto.

The resins used in the operation of forming the above-described dam DAM (S220) and the operation of forming the window coating layer WC (S230) may be the same material, but embodiments are not limited to the same material. For example, the resin may include at least one selected from the group consisting of polycarbonate, polymethylmethacrylate, polyimide, polyethylene terephthalate, polyacrylate, polyethylenenaphthalate, polyvinylidene chloride, polyvinylidene difluoride, polystyrene, an ethylene vinylalcohol copolymer, and triacetyl cellulose. However, the resin is not limited thereto.

The window coating layer WC may be formed (e.g., directly formed) on the anti-reflection layer RPL. For example, since the window coating layer WC is formed by coating the anti-reflection layer RPL without an additional adhesive member, the window WM including the window coating layer WC may have a small thickness. For example, the window WM may have a thickness t_{WM} of about 200 μm to about 700 μm.

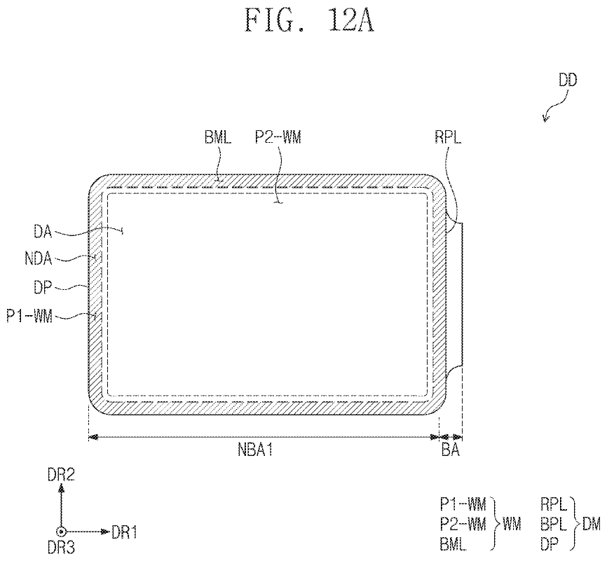

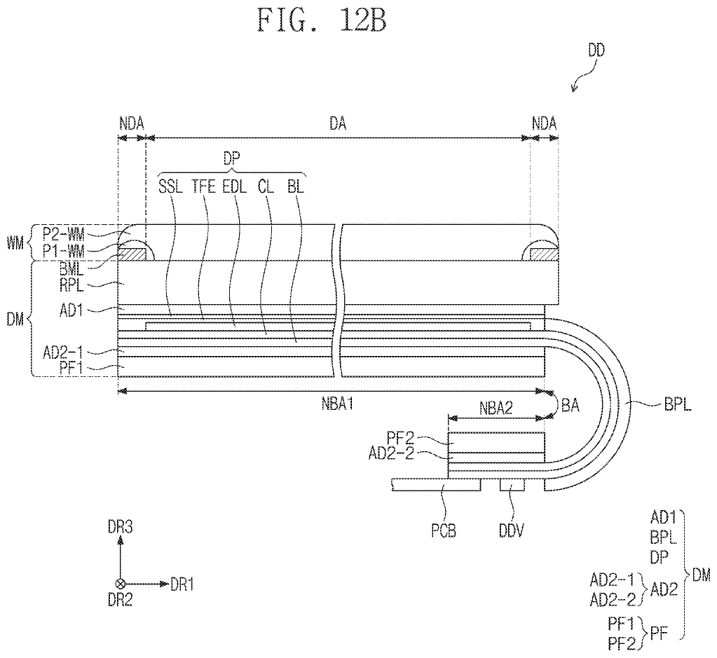

FIGS. 12A and 12B are respectively a schematic plan view and a schematic cross-sectional view illustrating a bent state of a display device DD finally obtained by forming a window WM on a display module DM.

In FIG. 12A, a second non-bending region NBA2 disposed below a first non-bending region NBA1 is omitted and a plane viewed in the third direction DR3 is illustrated.

Referring to FIG. 12B, since a panel protective layer PF is disposed only in the first and second non-bending regions NBA1 and NBA2 and is not disposed in a bending region BA, the thickness of the bending region BA of the display panel DP may be reduced. Thus, bending stress may be reduced. Accordingly, the display panel DP may be readily bent.

For example, a first adhesive layer AD1 may overlap the first non-bending region NBA1 and may not overlap the bending region BA. Accordingly, a portion of an anti-reflection layer RPL in the bending region BA may be spaced apart from the display panel DP, and the anti-reflection layer RPL and the window WM disposed on the anti-reflection layer RPL may not receive a bending stress during a bending operation, and may thus be maintained as parallel planes without being bent.

According to the description above, a display device according to an embodiment may be disposed (e.g., directly disposed) on a display module to have a small thickness, and include a window having a smooth edge portion, thereby improving reliability.

In a method of manufacturing a display device according to an embodiment, a resin having a viscosity within a various range may be used and it is unnecessary to perform an additional process when forming a window, thereby improving reliability and processability.

Although the embodiments have been described, it is understood that the inventive concept should not be limited to these embodiments but various changes and modifications can be made by one ordinary skilled in the art within the spirit and scope of the disclosure as hereinafter claimed. Therefore, the technical scope of the disclosure is not limited to the contents described in the detailed description of the specification, but should be determined by the claims.

What is claimed is:

1. A display device comprising:
a display panel;
an anti-reflection layer disposed on the display panel; and
a window disposed on the anti-reflection layer, wherein
the window includes:
a first portion including a first resin and disposed on an edge portion of the anti-reflection layer, and
a second portion including a second resin and covering at least a portion of the first portion, and
a curing rate of the first resin is greater than a curing rate of the second resin.

2. The display device of claim 1, wherein
the first portion of the window has a closed line shape in plan view, and
an upper surface of the first portion of the window has a curvature.

3. The display device of claim 1, wherein a space surrounded by the first portion of the window is covered by the second portion of the window.

4. The display device of claim 1, wherein the window is directly disposed on the anti-reflection layer.

5. The display device of claim 1, wherein
the display panel comprises a display region and a non-display region surrounding the display region,
the window further comprises a light blocking layer overlapping the non-display region in plan view, and
the first portion of the window is directly disposed on the light blocking layer.

6. The display device of claim 1, wherein
the display panel comprises a first non-bending region, a bending region, and a second non-bending region which are arranged along a first direction, and
the anti-reflection layer overlaps the first non-bending region and at least a portion of the bending region in plan view.

7. The display device of claim 1, further comprising:
an adhesive layer disposed between the display panel and the anti-reflection layer; and
a bending protective layer disposed on the display panel, wherein
the display panel includes:
a first non-bending region,
a bending region, and
a second non-bending region which are arranged along a first direction,
the adhesive layer overlaps the first non-bending region and does not overlap the bending region in plan view, and
the bending protective layer is spaced apart from the anti-reflection layer.

8. The display device of claim 1, wherein
the second portion of the window comprises:
a flat portion including a substantially flat upper surface; and
a curved portion including a curved upper surface and surrounding the flat portion in plan view,
the curved portion has a width of about 3 mm or less.

9. The display device of claim 1, wherein the window has a thickness of about 200 μm to about 700 μm.

10. A method of manufacturing a display device, the method comprising:
preparing a display module including a display panel and an anti-reflection layer disposed on the display panel; and
forming a window on the display module,
wherein the forming of the window includes:
forming a dam on an edge portion of the anti-reflection layer, and
forming a window coating layer on the anti-reflection layer.

11. The method of claim 10, wherein the forming of the dam comprises:
applying a resin on the edge portion of the anti-reflection layer; and
temporarily curing the resin.

12. The method of claim 10, wherein the forming of the window coating layer comprises:
applying a resin to cover a space, which is surrounded by the dam, and at least a portion of the dam; and
curing the dam and the resin.

13. The method of claim 10, wherein
the dam has a closed line shape in plan view, and
an upper surface of the dam has a curvature.

14. The method of claim 10, wherein the window coating layer is transparent.

15. The method of claim 10, wherein
the display panel comprises a display region and a non-display region surrounding the display region, and
the forming of the window further comprises forming a light blocking layer on the anti-reflection layer overlapping the non-display region in plan view.

16. The method of claim 15, wherein in the forming of the dam, the dam is formed on the light blocking layer.

17. The method of claim 10, wherein
the display panel comprises a first non-bending region, a bending region, and a second non-bending region which are arranged along a first direction, and
the anti-reflection layer overlaps the first non-bending region and at least a portion of the bending region in plan view.

18. The method of claim 10, wherein
the display module further comprises:
an adhesive layer disposed between the display panel and the anti-reflection layer, and
a bending protective layer disposed on the display panel,
the display panel comprises a first non-bending region, a bending region, and a second non-bending region which are arranged along a first direction,
the adhesive layer overlaps the first non-bending region and does not overlap the bending region in plan view, and
the bending protective layer is spaced apart from the anti-reflection layer.

19. The method of claim 10, wherein
the window coating layer comprises:
a flat portion including a substantially flat upper surface; and
a curved portion including a curved upper surface and surrounding the flat portion in plan view,
the curved portion has a width of about 3 mm or less.

20. The method of claim 10, wherein the window has a thickness of about 200 μm to about 700 μm.
